(19) United States
(12) Patent Application Publication
(10) Pub. No.: US 2019/0068204 A1
(43) Pub. Date: Feb. 28, 2019

(54) FREQUENCY LOCKING CIRCUITRY AND CLOCK DATA RECOVERY CIRCUITRY

(71) Applicant: Toshiba Memory Corporation, Tokyo (JP)

(72) Inventor: Tetsuya Yamaguchi, Yokosuka Kanagawa (JP)

(21) Appl. No.: 15/919,508

(22) Filed: Mar. 13, 2018

(30) Foreign Application Priority Data
Aug. 30, 2017 (JP) 2017-165877

(51) Int. Cl. H03L 7/08; H03L 7/083

(52) U.S. Cl. CPC H03L 7/0807; H03L 7/083

(57) ABSTRACT

A frequency locking circuitry has a counter to count a cycle number of a first clock signal included in one cycle of a second clock signal synchronized with the first clock signal, a generator to generate a frequency output code based on a result of comparison between the counted cycle number and a predetermined reference cycle number, and an oscillator to generate an oscillation signal having a frequency in accordance with the generated frequency output code. The generator changes a change value of the frequency output code in a plurality of ways until the counted cycle number reaches from an initial value to the reference cycle number.

### CROSS REFERENCE TO RELATED APPLICATIONS

This application is based upon and claims the benefit of priority from the prior Japanese Patent Application No. 2017-165877, filed on Aug. 30, 2017, the entire contents of which are incorporated herein by reference.

### FIELD

Embodiments relate to frequency locking circuitry and clock data recovery circuitry.

### BACKGROUND

Reception circuitry for receiving high-speed serial data is provided with clock data recovery circuitry (hereinafter, CDR circuitry) that detects a serial-data delimiter (edge) to extract a clock signal and data. The CDR circuitry is provided with frequency locking circuitry and phase locking circuitry. The frequency locking circuitry feeds-back an oscillation signal generated by a digital controlled oscillator to lock a frequency of the oscillation signal. In more detail, the frequency locking circuitry counts a cycle number of the above-mentioned oscillation signal included in one cycle of a reference signal and updates a frequency output code until the counted cycle number matches with a predetermined reference cycle number.

However, the cycle number of the oscillation signal included in one cycle of the reference signal is counted, for example, by the number of rising edges of the oscillation signal. Therefore, there are cases such that a rising edge is barely included in one cycle of the reference signal, or conversely, a rising edge is barely not included in one cycle of the reference signal, which result in that the counted cycle number is changed by ±1.

Moreover, in order to improve frequency locking accuracy, it is desirable to lower a frequency of the reference signal with respect to the frequency of the oscillation signal as much as possible. However, as the frequency of the reference signal is lowered with respect to the frequency of the oscillation signal, a time required for frequency locking is lengthened. Accordingly, it has been conventionally said that the time required for frequency locking and the frequency locking accuracy have a trade-off relationship.

### BRIEF DESCRIPTION OF THE DRAWINGS

FIG. 1 is a block diagram schematically showing a configuration of CDR circuitry provided with frequency locking circuitry according to a first embodiment;

FIG. 2 is a timing chart of a first clock signal that is an oscillation signal of a DCO and a second clock signal that is an output signal of a synchronizer;

FIG. 3 is a figure showing that a frequency output code and a cycle number change with time;

FIG. 4 is a figure enlarging part of FIG. 3;

FIG. 5 is a figure showing a correspondence relationship between the frequency output code and the cycle number;

FIG. 6 is a figure schematically showing durations in which the cycle number and the frequency output code change;

FIG. 7 is a figure explaining an operation of a code generator according to a comparative example;

FIG. 8 is a figure showing a correspondence relationship between a frequency output code and a cycle number according to the comparative example;

FIG. 9 is a flowchart showing an operation of a code generator according to the first embodiment;

FIG. 10 is a flowchart showing an operation of a code generator according to a second embodiment; and

FIG. 11 is a flowchart showing an operation of a code generator according to a third embodiment.

### DETAILED DESCRIPTION

A frequency locking circuitry according to one embodiment has a counter to count a cycle number of a first clock signal included in one cycle of a second clock signal synchronized with the first clock signal, a generator to generate a frequency output code based on a result of comparison between the counted cycle number and a predetermined reference cycle number, and an oscillator to generate an oscillation signal having a frequency in accordance with the generated frequency output code. The generator changes a change value of the frequency output code in a plurality of ways until the counted cycle number reaches from an initial value to the reference cycle number.

Embodiments will now be explained with reference to the accompanying drawings.

### First Embodiment

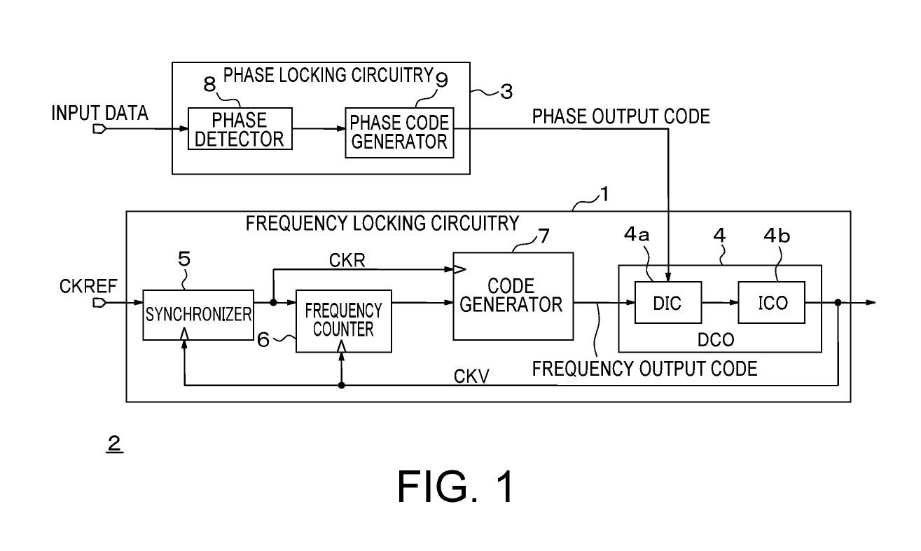

FIG. 1 is a block diagram schematically showing a configuration of CDR (Clock data Recovery) circuitry 2 provided with frequency locking circuitry 1 according to a first embodiment. The CDR circuitry 2 of FIG. 1 is provided with phase locking circuitry 3 in addition to the frequency locking circuitry 1.

The frequency locking circuitry 1 performs locking a frequency of an oscillation signal of a DCO (Digital Controlled Oscillator) 4. The frequency locking circuitry 1 has a synchronizer 5, a frequency counter 6, and a code generator 7.

The synchronizer 5 generates a second clock signal CKR that is acquired by synchronizing a reference clock signal CKREF having a fixed frequency with an oscillation signal (also referred to as a first clock signal) CKV of the DCO 4. The reference clock signal CKREF is, for example, a signal supplied from a controller not shown, which is asynchronous with the oscillation signal of the DCO 4. Therefore, the synchronizer 5 performs synchronization of the reference clock signal CKREF with the oscillation signal. It is presupposed in the present embodiment that a frequency of the oscillation signal of the DCO 4 is higher than the fixed frequency of the reference clock signal CKREF. Accordingly, it is possible to synchronize the reference clock signal CKREF with the oscillation signal (the first clock signal).

The frequency counter 6 counts a cycle number of the first clock signal included in one cycle of the second clock signal CKR that is synchronized with the first clock signal. It is presupposed in the present embodiment that an N (N being an integer of 1 or more) number of first clock signals are included in one cycle of the second clock signal CKR. The frequency counter 6, for example, counts the cycle number by means of the number of rising edges of the first clock signal included in one cycle of the second clock signal CKR.

The code generator 7 generates a frequency output code based on a result of comparison between the cycle number counted by the frequency counter 6 and a predetermined reference cycle number. In more detail, the code generator 7 changes a change value of the frequency output code in a plurality of ways until a count value of the frequency counter 6 reaches the reference cycle number from an initial value. In more specifically, the code generator 7 generates a frequency output code that corresponds to the reference cycle number by linear extrapolation based on a change value of the frequency output code while a cycle number counted by the frequency counter 6 changes by a predetermined value. The predetermined value is 1, for example. In this case, the code generator 7 generates a frequency output code that corresponds to the reference cycle number by the linear extrapolation based on a change value of the frequency output code before and after a change of 1 in the cycle number counted by the frequency counter 6. The predetermined value may be a value other than 1.

The DCO 4 includes a DIC (Digital-Current Converter) 4a and an ICO (Current-Controlled Oscillator) 4b. The DIC 4a generates a current signal in accordance with a frequency output code generated by the code generator 7 and a phase output code generated by the phase locking circuitry 3. The ICO 4b generates an oscillation signal having a frequency and a phase in accordance with the current signal generated by the DIC 4a. That is, the DCO 4 controls the frequency of the oscillation signal based on an output signal of the code generator 7 in the frequency locking circuitry 1, and controls the phase of the oscillation signal based on an output signal of the phase locking circuitry 3.

The phase locking circuitry 3 includes a phase detector 8 and a phase code generator 9. The phase detector 8 detects a phase of serial input data. The phase code generator 9 generates a phase code in accordance with the phase detected by the phase detector 8.

By detecting the phase of the serial input data, adjusting the phase of the oscillation signal, and controlling the frequency of the oscillation signal, the DCO 4 can generate an oscillation signal having a frequency and a phase with which the serial input data can be correctly taken in.

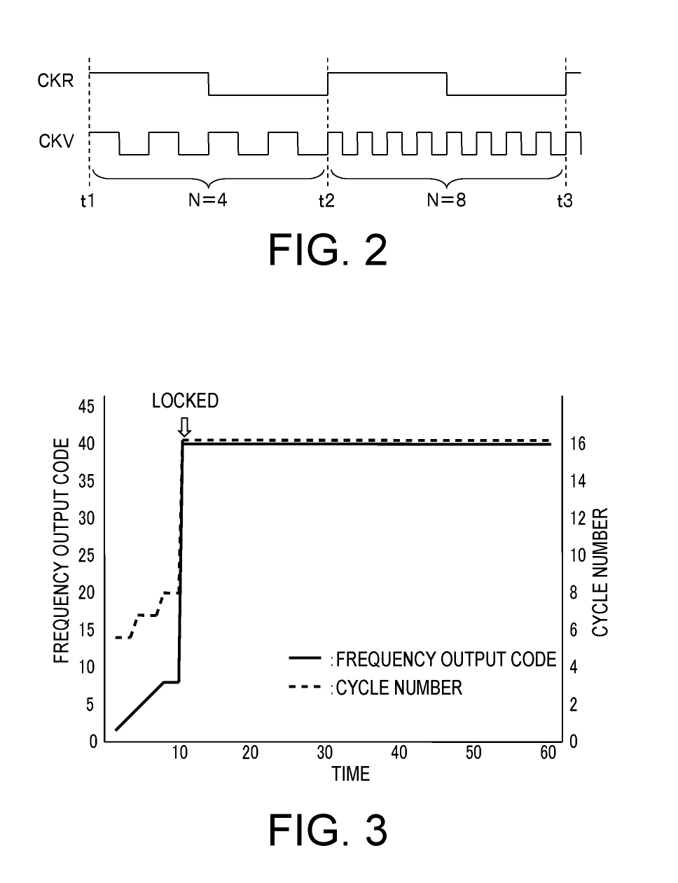

FIG. 2 is a timing chart of the first clock signal that is the oscillation signal of the DCO 4 and the second clock signal CKR that is the output signal of the synchronizer 5. Times t1 to t2 and t2 to t3 are each one cycle of the second clock signal CKR. FIG. shows an example that a duration between the times t1 to t2 is N=4, and a duration between the times t2 to t3 is N=8. In the duration between the times t1 to t2, 4 cycles of the first clock signal are included in one cycle of the second clock signal CKR. In the duration between the times t2 to t3, 8 cycles of the first clock signal are included in one cycle of the second clock signal CKR.

A reference cycle number is preset to the code generator 7, so that the code generator 7 generates a frequency output code in accordance with the reference cycle number. However, depending on an environmental condition such as temperature, a power supply voltage level, etc., a frequency output code corresponding to the reference cycle number may not always take the same value. In the present embodiment, it is performed, by adjusting the frequency output code, to finally match the count value of the frequency counter 6 with the reference cycle number.

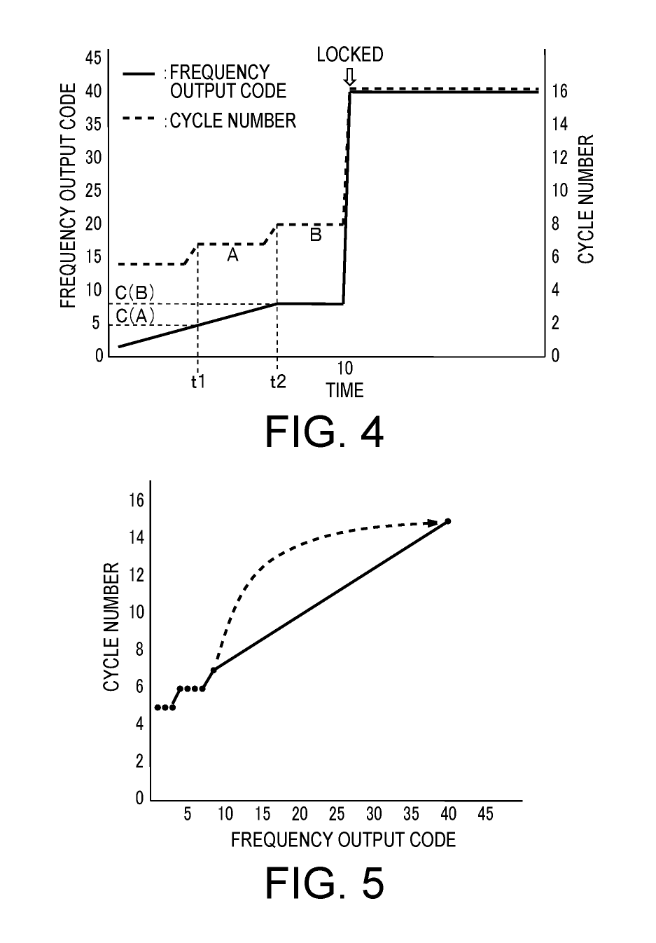

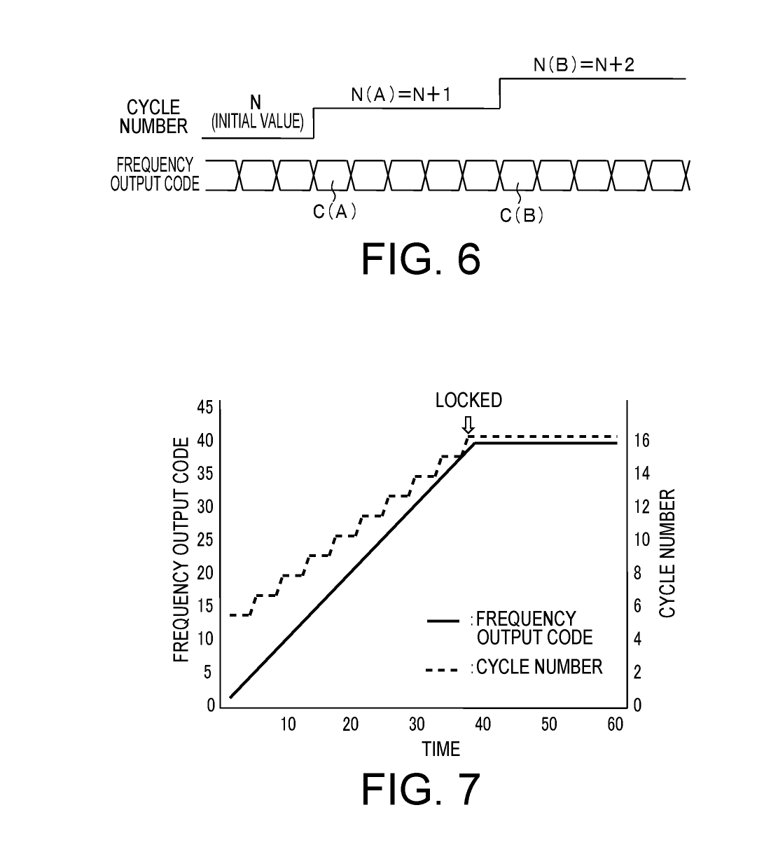

FIGS. 3 to 6 are figures explaining an operation of the code generator 7. FIG. 3 is a figure showing that the frequency output code and the cycle number change with time. FIG. 4 is a figure enlarging part of FIG. 3. In FIGS. 3 and 4, the abscissa indicates time, and the ordinate indicates the frequency output code and the cycle number counted by the frequency counter 6. FIG. 5 is a figure showing a correspondence relationship between the frequency output code and the cycle number. In FIG. 5, the abscissa indicates the frequency output code and the ordinate indicates the cycle number counted by the frequency counter 6. FIG. 6 is a figure schematically showing durations in which the cycle number and the frequency output code change.

As shown in FIGS. 3 to 6, the code generator 7 according to the present embodiment detects a change value of the frequency output code before and after that the count value of the frequency counter 6 increases by a predetermined value (for example, +1) and, based on the change value and by linear extrapolation, detects a frequency output code at a timing at which the count value of the frequency counter 6 reaches the reference cycle number. In more specifically, the code generator 7 calculates a difference (C(B)−C(A)) between frequency output codes C(A) and C(B), before and after that the count value of the frequency counter 6 increases by +1 during the times t1 to t2 of FIG. 4 to detect, by linear extrapolation, a frequency output code that corresponds to the reference cycle number. The linear extrapolation is, using two points on a straight line having a constant gradient, to determine the gradient and intercept, and find out the value of a given point on the straight line. FIG. 4 shows a correspondence relationship between the frequency output code and the cycle number. As long as a count value corresponding to the frequency output code C(A) and a count value corresponding to the frequency output code C(B) are found out, the gradient and intercept of the straight line in FIG. 4 can be determined, and hence, from this straight line, a frequency output code corresponding to the reference cycle number can be easily given.

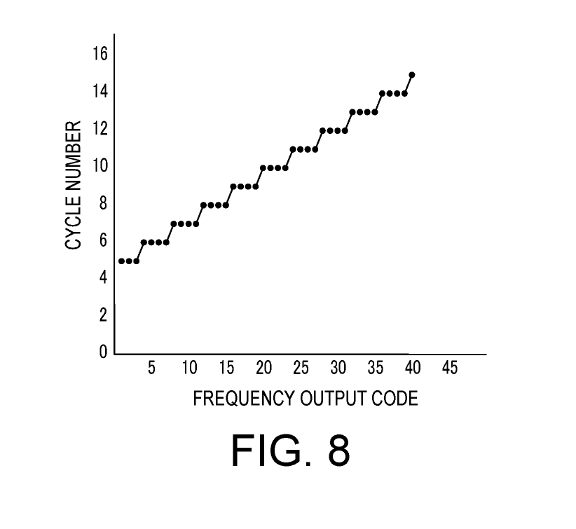

FIGS. 7 and 8 are figures explaining an operation of the code generator 7 according to a comparative example. In FIG. 7, in the same manner as in FIG. 3, the abscissa indicates time, and the ordinate indicates the frequency output code and the cycle number counted by the frequency counter 6. In FIG. 8, in the same manner as in FIG. 5, the abscissa indicates the frequency output code and the ordinate indicates the cycle number counted by the frequency counter 6.

The code generator 7 according to the comparative example lineally changes the frequency output code with a constant gradient. Therefore, the cycle number counted by the frequency counter 6 changes step by step, so that the cycle number requires a considerable time to reach the reference cycle number. In contrast, in the case of the present embodiment, the frequency output code is changed drastically at a moment at which the count value of the frequency counter 6 is updated from an initial value only once. Therefore, the time for the count value of the frequency counter 6 to reach the reference cycle number can be significantly shortened, compared to the comparative example.

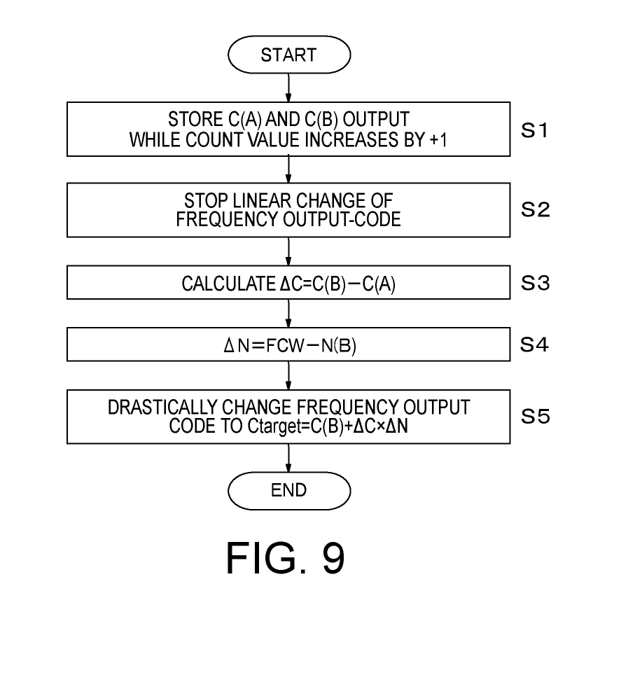

FIG. 9 is a flowchart showing an operation of the code generator 7 according to the first embodiment. First of all, the frequency output code output from the code generator 7 is lineally changed with time and then frequency output codes C(A) and C(B), before and after that a count value 1 of the frequency counter 6 increases by +1 from an initial value, are stored (step S1).

Subsequently, linear change, with time, of the frequency output code output from the code generator 7, is stopped once (step S2). Then, a difference in frequency output code ΔC=C(B)−C(A) is calculated (step S3). Subsequently, a difference ΔN=FCW−N(B) between a preset reference cycle number FCW (Frequency Control Word) and a count value N(B) of the frequency counter 6, which corresponds to the frequency output code C(B), is calculated (step S4). Subsequently, a target frequency output code Ctarget=C(B)+ΔC×ΔN is calculated to drastically change the frequency output code to the frequency output code Ctarget (step S5). In this way, without gradually changing the frequency output code, the target frequency output code Ctarget can be set in a short time.

As described above, in the first embodiment, based on the difference between the frequency output codes C(A) and C(B) before and after that the count value of the frequency counter 6 changes by +1 and on the preset reference cycle number FCW of the frequency counter 6, the frequency output code is changed drastically to set the target frequency output code Ctarget. Therefore, the frequency of the oscillation signal can be locked at high accuracy in a short time.

In the above-described example, although the difference between the frequency output codes C(A) and C(B) before and after that the count value of the frequency counter 6 changes by +1 is calculated, a difference between the frequency output codes C(A) and C(B) before and after a change by a predetermined value M other than +1 may be calculated. In this case, the target frequency output code is Ctarget=C(B)+ΔC×ΔN/M.

### Second Embodiment

Although the frequency locking circuitry 1 according to the second embodiment has the same block configuration as that shown in FIG. 1, the operation of the code generator 7 is different from that of the first embodiment. The code generator 7 according to the second embodiment gradually increases the change value of the frequency output code until the cycle number counted by the frequency counter 6 first exceeds the reference cycle number and then changes the frequency output code per minimum change value when the cycle number counted by the frequency counter 6 first exceeds the reference cycle number. In more specifically, the code generator 7 exponentially increases the change value of the frequency output code until the cycle number counted by the frequency counter 6 first exceeds the reference cycle number and then changes the frequency output code per minimum change value when the cycle number counted by the frequency counter 6 first exceeds the reference cycle number.

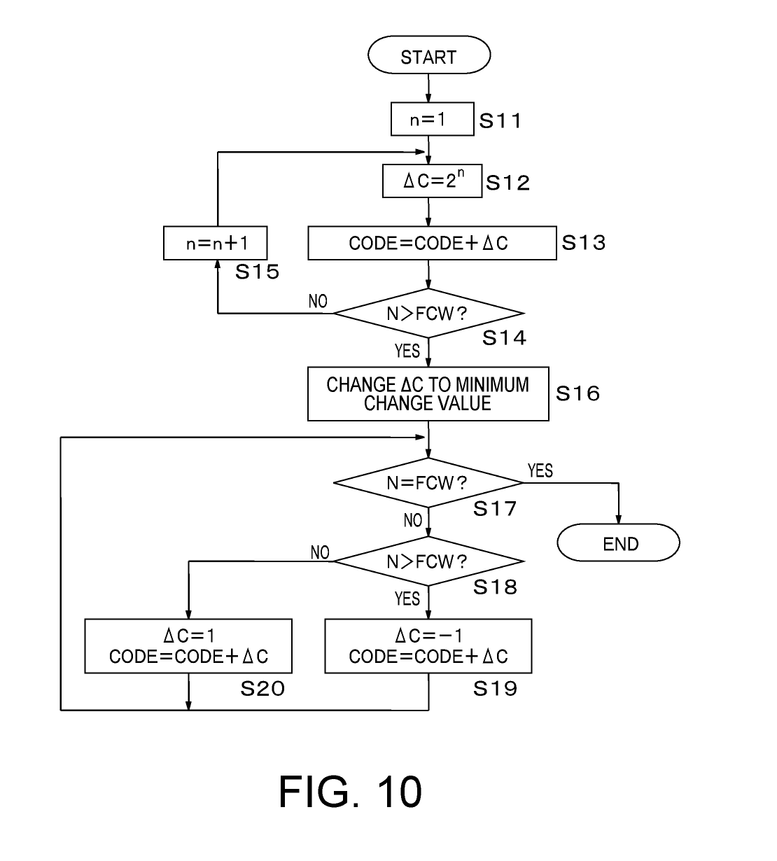

FIG. 10 is a flowchart showing an operation of the code generator 7 according to the second embodiment. First of all, an index number n, which is a power of 2, is initialized to 1 (step S11). Subsequently, a change value ΔC=2ⁿ of a frequency output code is calculated (step S12). Subsequently, a value obtained by adding the change value ΔC to the current frequency output code CODE is set as a new frequency output code CODE (step S13).

Subsequently, it is determined whether a count value N of the frequency counter 6, which corresponds to the new frequency output code CODE, is larger than a reference cycle number FCW, that is, whether or not N>FCW (step S14). If not N>FCW, n=n+1 is set (step S15), and then step S12 and the following steps are performed.

If N>FCW in step S14, ΔC is changed to a minimum change value (step S16). Here, the minimum change value is, for example, ΔC=±1. Subsequently, it is determined whether or not N=FCW (step S17). If N=FCW, the process of FIG. 10 ends. If not N=FCW, it is determined whether or not N>FCW (step S18). If N>FCW, ΔC=−1 is set (step S19), and then the process returns to step S17. If N≤FCW, ΔC=1 is set (step S20), and then the process returns to step S17.

As described above, in the second embodiment, in an early stage in which the frequency output code starts to be changed, the index number n is gradually increased to exponentially increase the frequency output code per change value ΔC=2ⁿ of the frequency output code, and hence the frequency output code can be increased in a short time. Moreover, when the count value N of the frequency counter 6, which corresponds to the frequency output code, first exceeds FCW, the change value ΔC of the frequency output code is decreased to the minimum change value to perform frequency locking, and hence it is possible to perform frequency fine adjustments. In this way, according to the second embodiment, in the same manner as the first embodiment, the frequency of the oscillation signal can be locked in a short time at high accuracy.

Especially, in the present embodiment, the frequency output code is exponentially increased to make the count value of the frequency counter 6 close to the reference cycle number in a short time and, thereafter, the change value ΔC of the frequency output code is decreased to the minimum change value. Therefore, not only that a frequency locking time can be shortened, but also that frequency fine adjustments can be performed.

Although, the example explained with respect to FIG. 10 is that the change value of the frequency output code is exponentially increased with a power of 2, it may be exponentially increased with a power of any numerical value other than 2.

### Third Embodiment

Although the frequency locking circuitry 1 according to the third embodiment has the same block configuration as that shown in FIG. 1, the operation of the code generator 7 is different from those of the first and second embodiments. The code generator 7 according to the third embodiment sets the change value of a frequency output code in an early stage to a predetermined large first change value and, thereafter, sets the change value to a second change value that is smaller than the first change value.

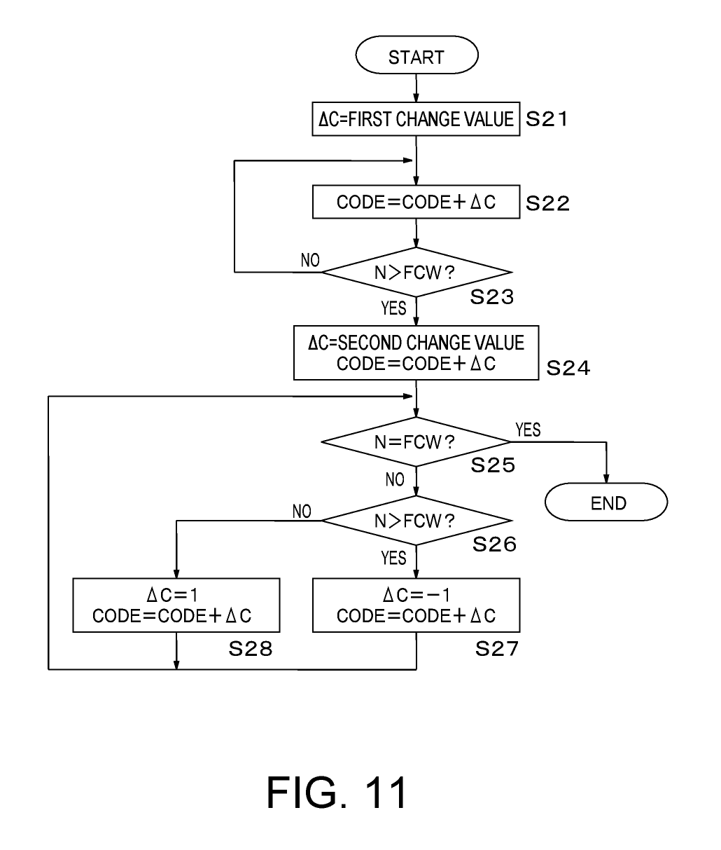

FIG. 11 is a flowchart showing an operation of the code generator 7 according to the third embodiment. First of all, a change value ΔC of the frequency output code is set to a predetermined first change value (step S21). Here, the first change value is a fixed value that is larger than a second change value for frequency fine adjustments which will be described later.

Subsequently, a value obtained by adding the change value ΔC to the current frequency output code CODE is set as a new frequency output code CODE (step S22). Subsequently, it is determined whether a count value N of the frequency counter 6, which corresponds to the new frequency output code CODE, first exceeds a reference cycle number FCW, that is, whether or not N>FCW for the first time (step S23). If still N≤FCW, step S22 and the flowing steps are performed. If N>FCW for the first time, the change value ΔC is changed to a second change value that is smaller than the first change value (step S24). Here, the second change value is a minimum change value, for example, ±1.

Subsequently, it is determined whether or not N=FCW (step S25). If N=FCW, the process of FIG. 11 ends. If not N=FCW, it is determined whether or not N>FCW (step S26). If N>FCW, ΔC=−1 is set (step S27), and then the process returns to step S25. If N≤FCW, ΔC=1 is set (step S28), and then the process returns to step S25.

As described above, in the third embodiment, two kinds of change values (first and second change values) are provided as the change value of the frequency output code, and, in an early stage in which the frequency output code starts to be changed, the frequency output code is changed per first change value that is larger than the second change value. Therefore, the frequency output code can be changed to be close to a desired frequency output code in a short time. Moreover, when the frequency output code becomes close to the desired frequency output code, the change value of the frequency output code is changed to the second change value, and hence frequency output-code fine adjustments can be done, so that the frequency of the oscillation signal can be locked in a short time and at high accuracy.

The frequency locking circuitry 1 according to each of the above-described first to third embodiments is configured without using a TDC (Time to Digital Converter), and hence, compared to the case where the TDC is used, the circuit configuration can be drastically simplified and power consumption can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A frequency locking circuitry comprising:
a counter to count a cycle number of a first clock signal included in one cycle of a second clock signal synchronized with the first clock signal;
a generator to generate a frequency output code based on a result of comparison between the counted cycle number and a predetermined reference cycle number; and
an oscillator to generate an oscillation signal having a frequency in accordance with the generated frequency output code,
wherein the generator changes a change value of the frequency output code in a plurality of ways until the counted cycle number reaches from an initial value to the reference cycle number.

2. The frequency locking circuitry of claim 1, wherein the code generator generates the frequency output code so that the counted cycle number coincides with the reference cycle number.

3. The frequency locking circuitry of claim 1, wherein the code generator generates a frequency output code corresponding to the reference cycle number by linear extrapolation based on a change value of the frequency output code while the counted cycle number changes by a predetermined value.

4. The frequency locking circuitry of claim 1, wherein the code generator generates a frequency output code corresponding to the reference cycle number by linear extrapolation based on a change value of the frequency output code before and after the counted cycle number changes by 1.

5. The frequency locking circuitry of claim 4, wherein when the change value of the frequency output code before and after the counted cycle number changes by 1 is ΔC, the frequency output code immediately after the counted cycle number changes by 1 is C(B), and a difference between a preset reference cycle number FCW and the frequency output code C(B) is ΔN, the code generator sets a target frequency output code Ctarget to Ctarget=C(B)+ΔC×ΔN.

6. The frequency locking circuitry of claim 1, wherein the code generator gradually increases a change value of the frequency output code until the counted cycle number first exceeds the reference cycle number, and changes the frequency output code per a minimum change value after the counted cycle number first exceeds the reference cycle number.

7. The frequency locking circuitry of claim 1, wherein the code generator increases a change value of the frequency output code based on an exponential function until the counted cycle number first exceeds the reference cycle number, and changes the frequency output code per a minimum change value after the counted cycle number first exceeds the reference cycle number.

8. The frequency locking circuitry of claim 1, wherein the code generator updates a change value of the frequency code based on the exponential function having an index number expressing the number of change count of the frequency output code until the counted cycle number first exceeds the reference cycle number, and changes the frequency output code per a minimum change value after the counted cycle number first exceeds the reference cycle number.

9. The frequency locking circuitry of claim 1, wherein the code generator increases a change value of the frequency output code per first change value until the counted cycle number first exceeds the reference cycle number, and changes the frequency output code per second change value smaller than the first change value after that the counted cycle number first exceeds the reference cycle number.

10. The frequency locking circuitry of claim 9, wherein the second change value comprises a minimum change value of the frequency output code.

11. A clock data recovery circuitry comprising:
a frequency locking circuitry to lock a frequency of an oscillation signal; and
a phase locking circuitry to lock a phase of an input data,
wherein the frequency locking circuitry comprises:
a counter to count a cycle number of a first clock signal included in one cycle of a second clock signal synchronized with the first clock signal;
a generator to generate a frequency output code based on a result of comparison between the counted cycle number and a predetermined reference cycle number; and
an oscillator to generate the oscillation signal having a frequency in accordance with the generated frequency output code and having a phase in accordance with an output signal of the phase locking circuitry,
wherein the generator changes a change value of the frequency output code in a plurality of ways until the counted cycle number reaches from an initial value to the reference cycle number.

12. The clock data recovery circuitry of claim 11, wherein the code generator generates the frequency output code so that the counted cycle number coincides with the reference cycle number.

13. The clock data recovery circuitry of claim 11, wherein the code generator generates a frequency output code corresponding to the reference cycle number by linear extrapolation based on a change value of the frequency output code while the counted cycle number changes by a predetermined value.

14. The clock data recovery circuitry of claim 11, wherein the code generator generates a frequency output code corresponding to the reference cycle number by linear extrapolation based on a change value of the frequency output code before and after the counted cycle number changes by 1.

15. The clock data recovery circuitry of claim 14, wherein when the change value of the frequency output code before and after the counted cycle number changes by 1 is ΔC, the frequency output code immediately after the counted cycle number changes by 1 is C(B), and a difference between a preset reference cycle number FCW and the frequency output code C(B) is ΔN, the code generator sets a target frequency output code Ctarget to Ctarget=C(B)+ΔC×ΔN.

16. The clock data recovery circuitry of claim 11, wherein the code generator gradually increases a change value of the frequency output code until counted the cycle number first exceeds the reference cycle number, and changes the frequency output code per minimum change value after the counted cycle number first exceeds the reference cycle number.

17. The clock data recovery circuitry of claim 11, wherein the code generator increases a change value of the frequency output code based on an exponential function until the counted cycle number counted first exceeds the reference cycle number, and changes the frequency output code per a minimum change value after the counted cycle number counted first exceeds the reference cycle number.

18. The clock data recovery circuitry of claim 11, wherein the code generator updates a change value of the frequency code based on the exponential function having an index number expressing the number of change count of the frequency output code until the counted cycle number first exceeds the reference cycle number, and changes the frequency output code per a minimum change value after the counted cycle number first exceeds the reference cycle number.

19. The clock data recovery circuitry of claim 11, wherein the code generator increases a change value of the frequency output code per first change value until the counted cycle number first exceeds the reference cycle number, and changes the frequency output code per second change value smaller than the first change value after that the counted cycle number first exceeds the reference cycle number.

20. The clock data recovery circuitry of claim 19, wherein the second change value comprises a minimum change value of the frequency output code.
